(19) United States
(12) Patent Application Publication
(10) Pub. No.: US 2011/0006388 A1
(43) Pub. Date: Jan. 13, 2011

(54) SEMICONDUCTOR DEVICE

(76) Inventor: Masafumi Kawanaka, Tokyo (JP)

Correspondence Address: Mr. Jackson Chen, 6535 N. STATE HWY 161, IRVING, TX, 75039, US

(21) Appl. No.: 12/919,460

(22) PCT Filed: Feb. 13, 2009
(86) PCT No.: PCT/JP2009/052377

§ 371 Date: Aug. 25, 2010

(30) Foreign Application Priority Data
Mar. 26, 2008 (JP) 2008 080743

(51) Int. Cl. H01L 29/66

(52) U.S. Cl. 257/467; 257/E29.347

(57) ABSTRACT

A semiconductor device which can actively dissipate heat in response to operation is provided. A Seebeck element 310 is buried as a thermoelectric conversion element. The Seebeck element 310 is provided inside a semiconductor element, and has one end disposed proximal to a heat generation part of the semiconductor element and the other end disposed in a distal side of the heat generation part. In addition, a Peltier element 320 is buried as a heat dissipation element. A Peltier element 320 has one end disposed proximal to the heat generation part and the other end disposed in a distal to the heat generation part, and the other end disposed in a distal end side of the heat generation part. A current according to the thermoelectromotive force generated by the Seebeck element 310 is applied to the Peltier element 320.

### TECHNICAL FIELD

The present invention relates to a semiconductor device.

### BACKGROUND ART

Semiconductor devices for computer controlling, power amplification, and high current generate an extremely large amount of heat. Various means to dissipate heat from such semiconductor devices are known. For example, a patent document 1 discloses a technique of thermally connecting a Peltier element to an insulated gate bipolar transistor (IGBT) for heat dissipation of the IGBT. Further, a Patent document 2 discloses a technique of burying a Peltier element into an IGBT element to actively dissipate power element from inside.

### [Patent Document 1]

Japanese Unexamined Patent Application Publication No. 2000-340723

### [Patent Document 2]

Japanese Unexamined Patent Application Publication No. 2007-227615

### DISCLOSURE OF INVENTION

### Technical Problem

However, in the patent document 1, the Peltier clement is thermally connected outside the IGBT. In this case, since an insulated substrate and a conductor region are disposed between the IGBT and the Peltier element, thermal resistance between the IGBT and the Peltier element becomes higher. As a result, heat dissipation efficiency becomes low, which keeps the temperature within the element high, and element destruction may be caused in the worst case.

The patent document 2 employs the configuration to bury a Peltier element into an IGBT element, and thus it is possible to actively dissipate heat of a semiconductor device that generates heat from inside. Further, by making the arrangement density of the embedded Peltier element coarse or dense, it is possible to actively dissipate the heat in a semiconductor device that does not uniquely generate heat from a part which generates or stores a large amount of heat.

However, in the semiconductor device, according to the operating condition, size of the heat generation volume or the heat storage volume and inplane distribution change greatly with time.

In the configuration of the patent document 2, the inplane distribution of heat dissipation efficiency is uniquely defined according to the arrangement of the Peltier element. Accordingly, it cannot respond to the operation of the semiconductor device at all and it is inevitable that heat remains inside the element.

It is an object of the present invention to provide a semiconductor device which can actively dissipate heat according to the operation.

### Technical Solution

The present invention is a semiconductor device including:

one or a plurality of semiconductor elements;

a thermoelectric conversion element located inside the semiconductor element, the thermoelectric conversion element having one end disposed proximal to a heat generation part of the semiconductor element and the other end disposed in a distal side of the heat generation part, the thermoelectric conversion element generating thermal electromotive force according to a difference of temperature between the one end and the other end; and

a heat dissipation element located inside the semiconductor element, the heat dissipation element having one end disposed proximal to the heat generation part and the other end disposed in a distal end side of the heat generation part, the heat dissipation element moving a heat from the one end to the other end by a current according to the thermal electromotive force generated by the thermoelectric conversion element being applied to the heat dissipation element.

### Advantageous Effects

According to the present invention, a semiconductor device can actively dissipate heat from a heat generation part according to the temperature of the position that is proximal to the heat generation part of the semiconductor element. As a result, a semiconductor device can be provided in which element operation is stable by actively dissipating heat according to the operation.

### BRIEF DESCRIPTION OF DRAWINGS

FIG. 1 shows a configuration in accordance with a first exemplary embodiment;

FIG. 2 shows an enlarged cross-sectional view of a Seebeck element in the first exemplary embodiment;

FIG. 3 shows an enlarged cross-sectional view of a Peltier element in the first exemplary embodiment;

FIG. 4 shows cross-sectional views of one semiconductor element, each showing different surfaces parallel with each other in a second exemplary embodiment; FIG. 4(a) shows a Seebeck element and FIG. 4(b) shows a Peltier element;

FIG. S shows a configuration in accordance with a third exemplary embodiment;

FIG. 6 shows a configuration in accordance with the third exemplary embodiment;

FIG. 7 shows a configuration in accordance with the third exemplary embodiment; and

FIG. 8 shows a configuration that implementes the present invention by minimum elements.

### EXPLANATION OF REFERENCE

100 BIPOLARTRANSISTOR
200 SEMICOMDUCTOR ELEMENT PART
201 SILICON SUBSTRATE
202 N-TYPE SUBCOLLECTOR LAYER
203 N-TYPE COLLECTOR LAYER
204 SELECTIVE ION-IMPLANTED COLLECTOR
205 N-TYPE COLLECTOR LAYER
206 P-TYPE BASE LAYER
207 N-TYPE EMITTER LAYER
208 ELEMENT ISOLATION LAYER
209 ELEMENT ISOLATION LAYER
210 INTERLAYER INSULATONG LAYER
211 INTERLAYER INSULATONG LAYER
212 DEEP TRENCH ISOLATION
300 HEAT DEALING MEANS
310 SEEBECK ELEMENT
311 N-TYPE SEMICOMDUCTOR
312 P-TYPE SEMICOMDUCTOR
313 INTERLAYER INSULATING FILM
320 PELTIER ELEMENT
330 AMPLIFIER CIRCUIT
400 HEAT DEALING MEANS
410 SEEBECK ELEMENT
411 N-TYPE SEMICOMDUCTOR
412 P-TYPE SEMICOMDUCTOR
413 INTERLAYER INSULATING LAYER
420 PELTIER ELEMENT
430 AMPLIFIER CIRCUIT
500 SEMICOMDUCTOR DEVICE
510 MULTIPLE BIPOLAR TRANSISTOR
501 SEMICOMDUCTOR SUBSTRATE
520 SEEBECK ELEMENT
530 PELTIER ELEMENT
540 FINGER

### BEST MODE FOR CARRYING OUT THE INVENTION

Exemplary embodiments of the present invention will be shown in the drawings and described with reference symbols of each element in the drawings.

### First Exemplary Embodiment

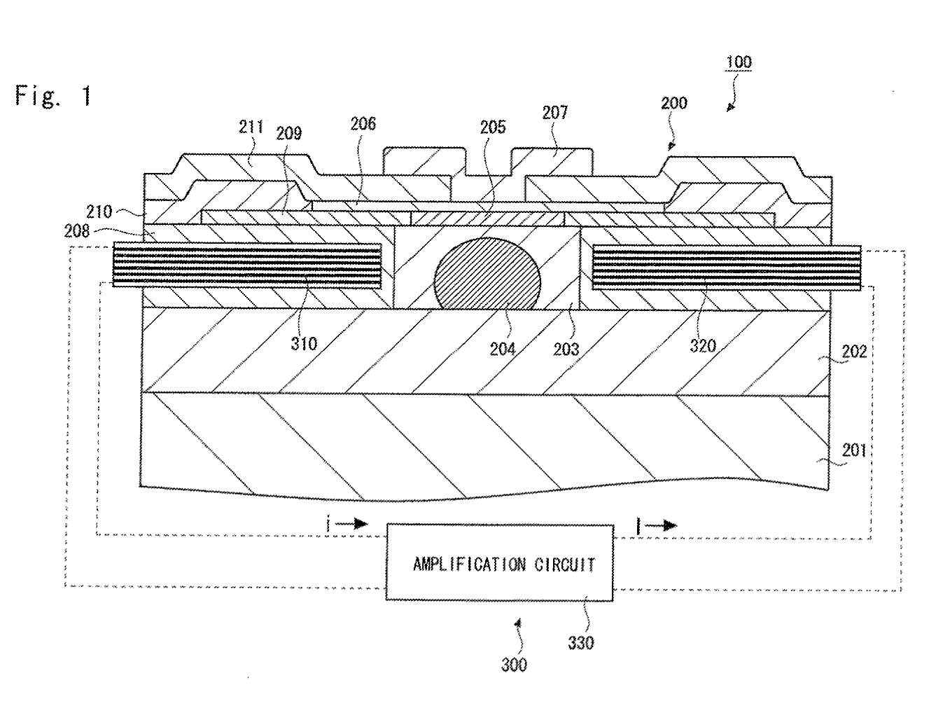

FIG. 1 shows a configuration of a first exemplary embodiment in accordance with a semiconductor device of the present invention.

The first exemplary embodiment is described with a bipolar transistor as a example as the semiconductor device. However, the invention is not limited to this example, but the present invention is applicable to CMOS (Complementary Metal Oxide Semiconductor), SiLDMOS (Silicon Laterally Diffused MOS), compound FET (Field Effect Transistor), SiBT (Silicon Bipolar Transistor), SiGeHBT (Silicon Germanium Heterojunction Bipolar Transistor), compound HBT, IGBT, for example, as a matter of couse.

In a semiconductor device (a bipolar transistor) 100 in accordance with this exemplary embodiment includes a semiconductor element part 200 to function as a semiconductor element, and a heat dealing means 300 that is included in the semiconductor element part and deals with the heat generated depending on the operation of the semiconductor element part.

As shown in the cross-sectional view of FIG. 1, the semiconductor element part 200 includes a silicon substrate 201, a high density, n-type subcollector layer 202, an n-type collector layer 203, a selective ion-implanted collector 204, an n-type collector layer 205, a p-type base layer 206, an n-type emitter layer 207, element isolation layers 208 and 209, interlayer insulating layers 210 and 211. The semiconductor element part 200 has a structure of the transistor of so-called NPN type. In such a structure, the SIC (selective ion-implanted collector) 204 and the n-type collector 205 generate the most heat during the operation.

The heat dealing mean 300 includes a Seebeck element 310 as a thermoelectric conversion element, a Peltier element 320 as a heat dissipation element, and an amplifier circuit 330 which applies an electric current to the Peltier element 320 according to a current value received from the Seebeck element 310.

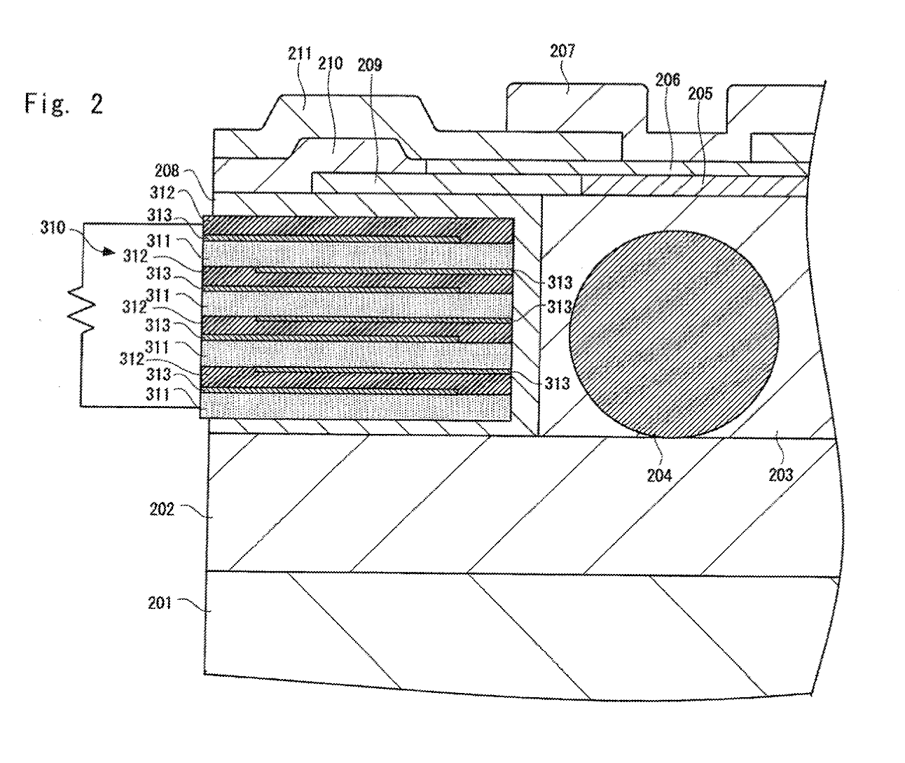

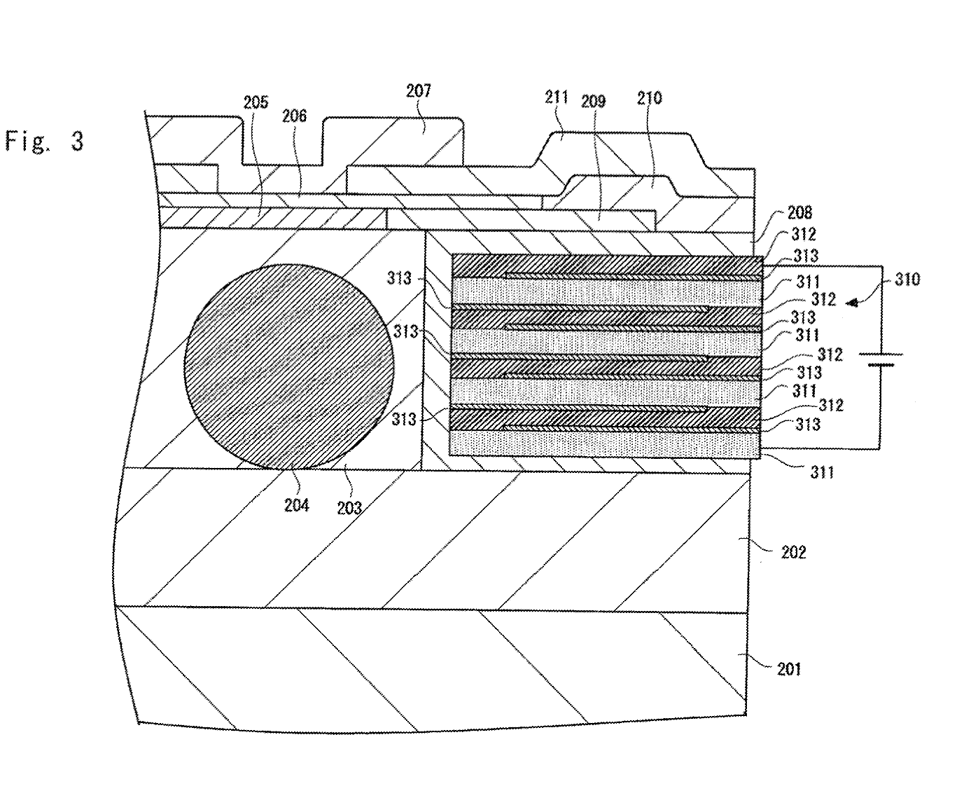

FIG. 2 shows an enlarged cross-sectional view of the Seebeck element 310, and FIG. 3 shows an enlarged cross-sectional view of the Peltier element.

The Seebeck element 310 and the Peltier element 320 are buried in the element isolation layer (STI; Shallow Trench Isolation) 208 adjacent to the n-type collector layer 203.

The Seebeck element 310 and the Peltier element 320 essentially have the same configuration. The Seebeck element 310 and the Peltier element 320 include n-type semiconductor 311 and a p-type semiconductor 312 serially-connected, and the same number of n-type semiconductors 311 and p-type semiconductors 312 are laminated alternately. Interlayer insulating films 313 are arranged between the layers between the n-type semiconductors 311 and the p-type semiconductors 312 to open one ends and the other ends alternately so that connection portions are formed only in one ends and the other ends while keeping the electrically serial connection.

Such Seebeck element 310 and Peltier element 320 can be formed by CVD (Chemical Vavor Deposition).

Note that, the n-type semiconductor and the p-type semiconductor include, as an example, SiGe or Bi₂Te₃.

When SiGe is used as a material, SiGe has a high affinity with a silicon process, and the semiconductor device in which a Seebeck element and a Peltier element are buried can be integrated on one ctip.

Also, when Bi₂Te₃ is used as a material, Bi₂Te₃ is effective and suitable to form the heat dealing means of the semiconductor device since the highest performance is achieved around 400 K.

In FIG. 2, the Seebeck element 310 is buried in the element isolation layer (STI) 208. The Seebeck element 310 is arranged so that one end is made closer to the selective ion-implanted collector 204 and the n-type collector 205, and the other end is made apart from the selective ion-implanted collector 204 and the n-type collector 205. It is preferable that the other end side has a constant temperature. The other end side may have the constant temperature because it is made apart from a heat source, or may be cooled to achieve the constant temperature using a radiation fin or a refrigerant.

Also, in the other end, an electrode is formed in each end corresponding to the top and the tail of the connection of the n-type semiconductors 311 and the p-type semiconductors 312, and it is connected to the amplification circuit 330.

Note that, in FIG. 2, a resistor is shown as well to clearly show generation of thermal electromotive force.

In FIG. 3, the Peltier element 320 is buried in the element isolation layer (STI) 208. The Peltier element 320 is arranged so that one end is made closer to the selective ion-implanted collector 204 and the n-type collector 205, and the other end is made apart from the selective ion-implanted collector 204 and the n-type collector 205.

In the other end, an electrode is formed in each end corresponding to the top and the tail of the connection of the n-type semiconductors 311 and the p-type semiconductors 312, and it is connected to the amplification circuit 330.

In this case, in one end side, current flows in the np direction; in the other end side, a DC power supply in the amplification circuit is connected to the Peltier element 320 so that current flows in the pn direction

Note that, in FIG. 3, a DC power supply is clearly shown as well to show the connection of the plus and minus of current.

The operation of the first exemplary embodiment including such a configuration is described.

A predetermined signal is given, and the semiconductor element part 200 starts the operation. Then heat is generated in the selective ion-implanted collector 204 and the n-type collector 205. The generated heat instantly transfers to one end of the Seebeck element 310 that is arranged nearby. In this way, while the temperature of one end side becomes high by heat transferring to one end of the Seebeck element 310, the temperature of the other end is kept constant. Then, in one end of the Seebeck element 310, current flows in the np direction (direction from n-type semiconductor to p-type semiconductor); in the other end, thermal electromotive force is generated so that current flows in the pn direction. Current i generated in this way by thermal electromotive force is input into the amplification circuit 330.

The amlification circuit 330 amplifies current i by this thermal electromotive force, and applies current l to the Peltier element 320. Then heat is absorbed in the one end side of the Peltier element 320, and heat is released in the other side thereof. Although the one end side of the Peltier element 320 is arranged close to the selective ion-implanted collector 204 and the n-type collector 205 that generate heat, heat from this heat generation part is absorbed instantly and the temperature of the heat generation part is reduced.

According to the first exemplary embodiment including such a configuration, the next effect can be produced.

(1) The Seebeck element 310 is buried with one end arranged to be made close to the heat generation part.

Since one end of the Seebeck element is extremely close to the heat generation part as stated above, only a slight increase in temperature in the heat generation part of the semiconductor element part causes difference of temperature between one end and the other end of the Seebeck element. Then a thermal electromotive force is generated in the Seebeck element immediately. This thermal electromotive force can apply current to the Peltier element, and release the heat of the heat generation part. The Seebeck element has high sensitivity to the rise in temperature of the heat generation part as stated above, thereby making it possible to immediately react to the operation of the semiconductor element for releasing the heat and to prevent the heat from being stored within the semiconductor.

(2) The one end of the Peltier element 320 is located proximal to the heat generation part of the semiconductor element part, thereby making it possible to instantly cool the heat generation part by the Peltier element 320 absorbing the heat, and to prevent the heat from being stored in the semiconductor element.

### Second Exemplary Embodiment

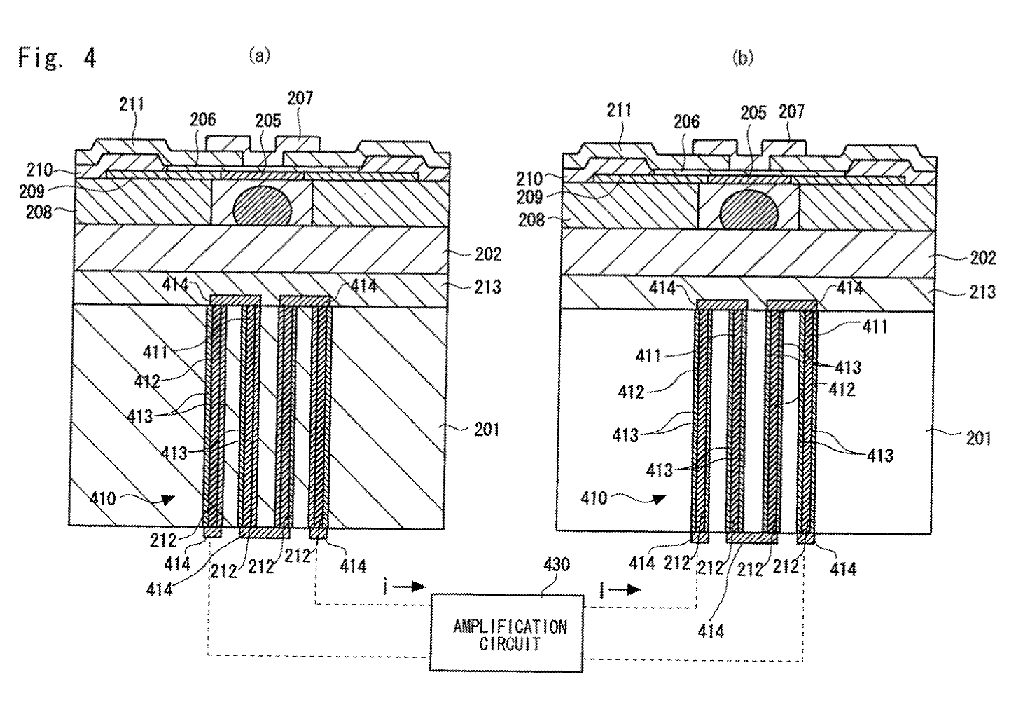

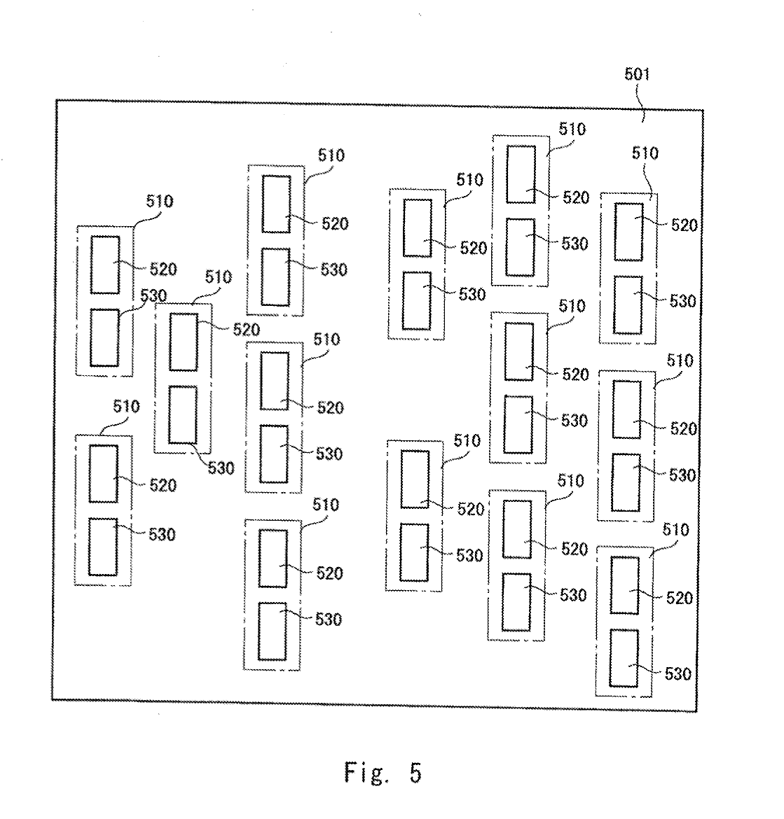

Next, a second exemplary embodiment of the present invention is described with reference to FIG. 4.

FIG. 4(a) and FIG. 4(b) are cross-sectional views of one semiconductor element, each showing different surfaces parallel with each other; FIG. 4(a) shows a Seebeck element, FIG. 4(b) shows a Peltier element.

In the second exemplary embodiment as well, a heat dealing means 400 includes a thermoelectric conversion element (Seebeck element) 410, a heat dissipation element (Peltier element) 420, and an amplifier circuit 430.

In the second exemplary embodiment, a plurality of DTIs (deep trench isolations) 212 are formed in the silicon substrate 201, and n-type semiconductors 411 and p-type semiconductors 412 are alternately buried in these DTIs 212.

Note that interlayer insulating layer 413 are disposed, between inner walls of the DTIs 212 and the n-type semiconductors 411/p type semiconductors 412.

Metal electrodes 414 are located in the upper part and the lower part so that the n-type semiconductors 411 and the p-type semiconductors 412 are connected in series.

A silicon oxide film 213 is located on the upper electrodes 414, so as to form a SOI (Silicon on Insulator) substrate. Herewith the SOI substrate into which the Seebeck element 410 and the Peltier element 420 are buried is provided. The remaining semiconductor element parts are formed on the SOI layer immediately above the Seebeck element 410 and the Peltier element 420. Particularly, the selective ion-implanted collector 204 and the n-type collector layer 205 that are heat generation part are located immediately above the Seebeck element 410 and the Peltier element 420.

Note that, similarly to the first exemplary embodiment, the current by the thermal electromotive force generated in the Seebeck element 410 is input into the amplification circuit 430, and the direct current from the amplification circuit 430 is applied to the Peltier element 420.

According to such a configuration, since the heat generation part of the semiconductor element (selective ion-implanted collector 204 and n-type collector 205) is formed immediately above the Seebeck element 410 and the Peltier element 420 that are buried in the silicon substrate 201, the heat generation part, the Seebeck element 410, and the Peltier element 420 are located extremely close to each other. Therefore, the similar effect as in the first exemplary embodiment is produced.

### Third Exemplary Embodiment

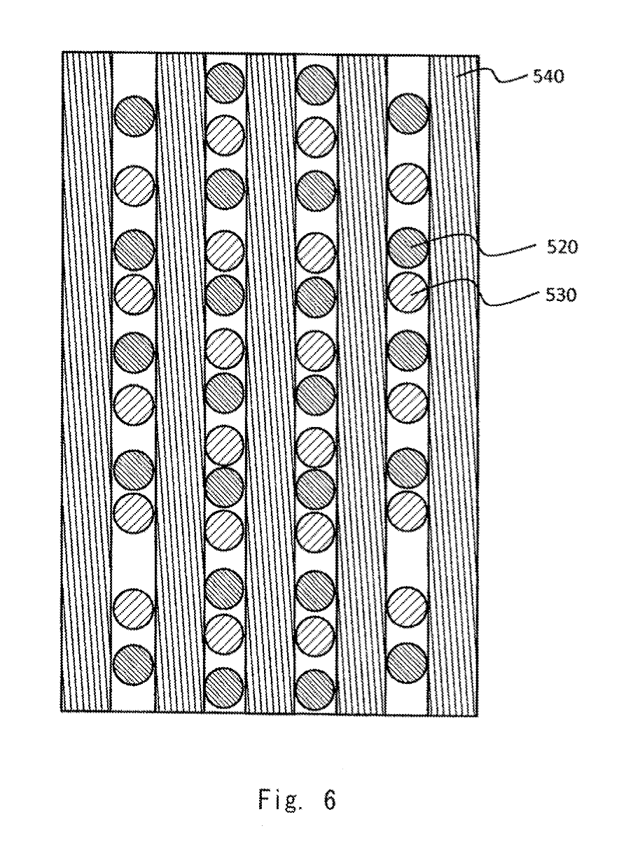

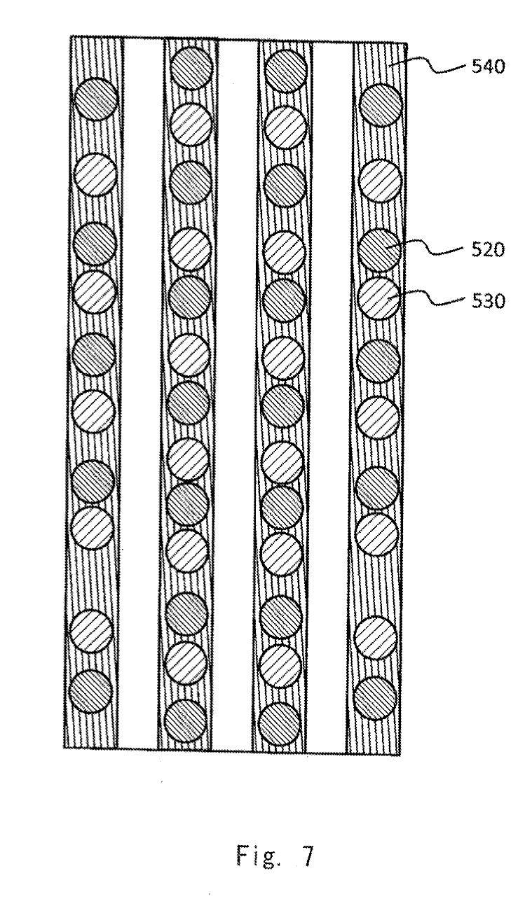

Next, a third exemplary embodiment of the present invention is described with reference to FIG. 5, FIG. 6, and FIG. 7.

A semiconductor device 500 according to the third exemplary embodiment is an example showing a case in which the present invention is applied to a transistor of the multi-finger type.

In FIG. 5, multiple bipolar transistors 510 are arranged in lines in one semiconductor substrate 501. Even in this case, as shown FIG. 5, a plurality of sets of Seebeck elements 520 and Peltier elements 530 are disposed at the predetermined positions in a chip.

According to such a configuration, active heat dissipation is enabled to the operation of the semiconductor element in a wide range, thereby making it possible to prevent uneven deviation such as local heat storage in a chip, and to keep appropriate temperature of the device as a whole.

When multiple semiconductor elements and multiple heat dealing means are combined as in the third exemplary embodiment, it is preferable to make the arrangement density of the heat generation part coarse or dense corresponding to the characteristic of the multi-cell device. For example, the heat dealing means is intensively arranged at positions where a large amount of heat is supposed to be released.

The arrangement density should not be limited by numerical values particularly. Any state in which arrangement density varies on a plane surface will be within the spirit of the present invention.

Now, FIG. 6 and FIG. 7 show the state in which Peltier elements (heat dissipation elements) 530 and Seebeck elements (thermoelectric conversion elements) 520 described in the above exemplary embodiments are arranged in a plurality of multi-finger devices having a plurality of slim shape fingers 540. The reference number 540 is a gate which corresponds to the finger, and represents a heat generation part of the multi-finger device.

The arrangement of the Peltier element (heat dissipation element) and the Seebeck element (thermoelectric conversion element) described in the first exemplary embodiment is applied in FIG. 6, and the arrangement of the Peltier element (heat dissipation element) and the Seebeck element (thermoelectric conversion element) described in the second exemplary embodiment is applied in FIG. 7.

In the semiconductor device having a plurality of elongated fingers 540, the central area releases much heat and the temperature of this area tends to increase. Thus, as shown in FIG. 6 and FIG. 7, the Peltier elements 530 and the Seebeck elements 520 are intensively arranged in the central area.

According to such a configuration, active heat dissipation is enabled to the operation of the semiconductor element in a wide range, and particularly, heat is intensively released in the area that releases much heat, thereby making it possible to prevent uneven deviation such as local heat storage in a chip, and to keep appropriate temperature of the device as a whole.

Note that the Seebeck element 520 and the Peltier element 530 need not have one-on-one correspondence, and but the Peltier element 530 may be driven by current provided from a plurality of the Seebeck elements 520.

Alternatively, one Seebeck element 520 may function as a temperature monitor to control the operation of a plurality of Peltier elements 530.

Note that the present invention is not limited to the above-described exemplary embodiments, but various modifications can be made without departing from the scope and spirit of the present invention.

In the exemplary embodiments described above, an amplification circuit is arranged between a Seebeck element and a Peltier element, and current from the Seebeck element is input to the amplification circuit, and the amplified direct current is applied to the Peltier element. However, the amplification circuit may be omitted.

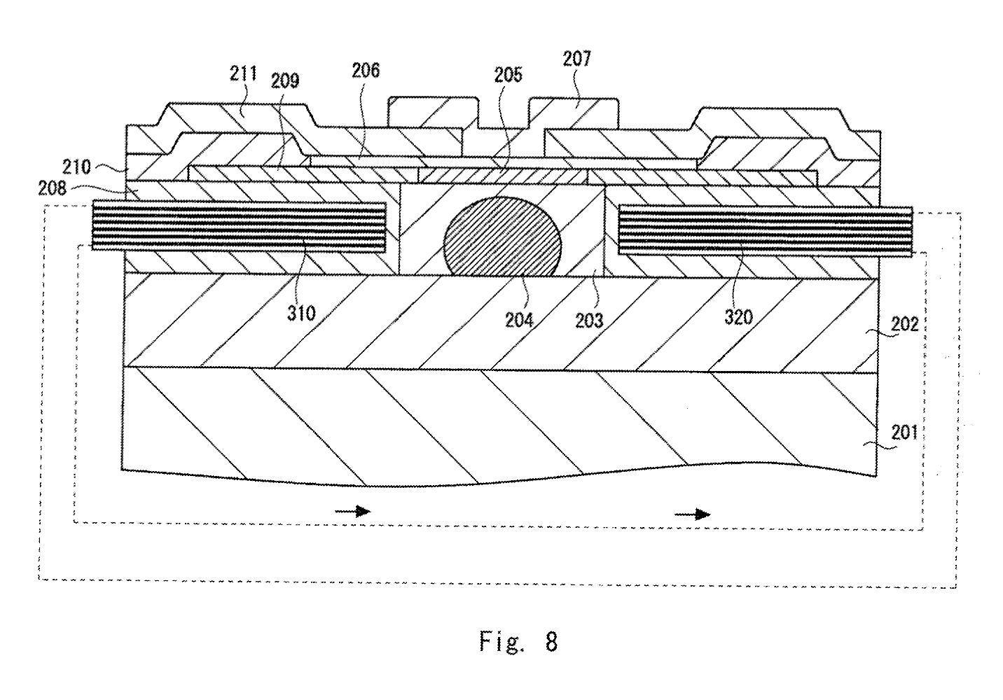

That is, as shown in FIG. 8, all that is required is that a heat dissipation element (Peltier element) 320 and a thermoelectric conversion element (Seebeck element) 310 are buried in a semiconductor element part 200, and the heat dissipation element (Peltier element) 320 is driven in accordance with an electric current from the thermoelectric conversion element (Seebeck element) 310.

At this time, the current from the thermoelectric conversion element (Seebeck element) 310 may be directly input to the heat dissipation element (Peltier element) 320.

Since one end of the Seebeck element 310 is located extremely close to the heat generation part, in the present invention, extremely high temperature is obtained. Therefore, sufficient cooling effect can be produced even if an electric current from the Seebeck element 310 is directly applied to the Peltier element 320 since big electromotive force is provided by the Seebeck element 310. Then, a significant effect can be produced that the semiconductor element can be cooled actively and effectively without the complicated structures such as an amplification circuit.

Alternatively, the temperature control part is located between the thermoelectric conversion element (Seebeck element) and the heat dissipation element (Peltier element), and this temperature control part may be composed of a heating detecting part detecting a rise in temperature in the heat generation part in the semiconductor element by current from the thermoelectric conversion element, and a current control part controlling current applied to heat dissipation element (Peltier element) based on detection of the temperature rising.

Although the present invention has been described with reference to the exemplary embodiments, the present invention is not limited to them. The structures and the details of the present invention may be variously changed in a way that those skilled in the art can understand within the scope of the present invention.

This application claims the benefit of priority, and incorporates herein by reference in its entirety, the following Japanese application Japanese Patent Application No. 2008-080743 filed on Mar. 26, 2008.

### INDUSTRIAL APPLICABILITY

The present invention can be applicable to a semiconductor device. The present invention is particularly applicable to a semiconductor that releases much heat.

1. A semiconductor device, comprising:
one or a plurality of semiconductor elements;
a thermoelectric conversion element located inside the semiconductor element, the thermoelectric conversion element having one end disposed proximal to a heat generation part of the semiconductor element and the other end disposed in a distal side of the heat generation part, the thermoelectric conversion element generating thermal electromotive force according to a difference of temperature between the one end and the other end; and
a heat dissipation element located inside the semiconductor element, the heat dissipation element having one end disposed proximal to the heat generation part and the other end disposed in a distal end side of the heat generation part, the heat dissipation element moving a heat from the one end to the other end by a current according to the thermal electromotive force generated by the thermoelectric conversion element being applied to the heat dissipation element.

2. The semiconductor device according to claim 1, wherein a current value input into the heat dissipation element is controlled according to a temperature of the heat generation part obtained based on the thermal electromotive force of the thermoelectric conversion element.

3. The semiconductor device according to claim 1, wherein a current obtained by the thermal electromotive force of the thermoelectric conversion element is transmitted to the heat dissipation element directly or after being amplified.

4. The semiconductor device according to claim 1, wherein the thermoelectric conversion element and the heat dissipation element are intensively arranged close to the semiconductor element which releases substantial amount of heat according to heat release volume based on operation amount of the semiconductor element that constitutes the semiconductor device, and the density of the thermoelectric conversion element and the heat dissipation element is made low near the semiconductor element which releases fewer amount of heat and has small operation amount.

5. The semiconductor device according to claim 1, wherein the thermoelectric conversion element is a Seebeck element, and the heat dissipation element is a Peltier element.

6. The semiconductor device according to claim 1, wherein at least one of the thermoelectric conversion element and the heat dissipation element includes SiGe as a configuration material.

7. The semiconductor device according to claim 1, wherein at least one of the thermoelectric conversion element and the heat dissipation element includes Bi₂Te₃ as a configuration material.

8. The semiconductor device according to claim 2, wherein the thermoelectric conversion element and the heat dissipation element are intensively arranged close to the semiconductor element which releases substantial amount of heat according to heat release volume based on operation amount of the semiconductor element that constitutes the semiconductor device, and the density of the thermoelectric conversion element and the heat dissipation element is made low near the semiconductor element which releases fewer amount of heat and has small operation amount.

9. The semiconductor device according to claim 3, wherein the thermoelectric conversion element and the heat dissipation element are intensively arranged close to the semiconductor element which releases substantial amount of heat according to heat release volume based on operation amount of the semiconductor element that constitutes the semiconductor device, and the density of the thermoelectric conversion element and the heat dissipation element is made low near the semiconductor element which releases fewer amount of heat and has small operation amount.

10. The semiconductor device according to claim 2, wherein the thermoelectric conversion element is a Seebeck element, and the heat dissipation element is a Peltier element.

11. The semiconductor device according to claim 3, wherein the thermoelectric conversion element is a Seebeck element, and the heat dissipation element is a Peltier element.

12. The semiconductor device according to claim 4, wherein the thermoelectric conversion element is a Seebeck element, and the heat dissipation element is a Peltier element.

13. The semiconductor device according to claim 2, wherein at least one of the thermoelectric conversion element and the heat dissipation element includes SiGe as a configuration material.

14. The semiconductor device according to claim 3, wherein at least one of the thermoelectric conversion element and the heat dissipation element includes SiGe as a configuration material.

15. The semiconductor device according to claim 4, wherein at least one of the thermoelectric conversion element and the heat dissipation element includes SiGe as a configuration material.

16. The semiconductor device according to claim 5, wherein at least one of the thermoelectric conversion element and the heat dissipation element includes SiGe as a configuration material.

17. The semiconductor device according to claim 2, wherein at least one of the thermoelectric conversion element and the heat dissipation element includes Bi₂Te₃ as a configuration material.

18. The semiconductor device according to claim 3, wherein at least one of the thermoelectric conversion element and the heat dissipation element includes Bi₂Te₃ as a configuration material.

19. The semiconductor device according to claim 4, wherein at least one of the thermoelectric conversion element and the heat dissipation element includes Bi₂Te₃ as a configuration material.

20. The semiconductor device according to claim 5, wherein at least one of the thermoelectric conversion element and the heat dissipation element includes Bi₂Te₃ as a configuration material.
